(19) United States
(12) Patent Application Publication
(10) Pub. No.: US 2025/0048883 A1
(43) Pub. Date: Feb. 6, 2025

(54) PIXEL, MANUFACTURING METHOD THEREOF, AND DISPLAY DEVICE INCLUDING THE SAME

(71) Applicant: Samsung Display Co., Ltd., Yongin-Si (KR)

(72) Inventors: Kyung Bae KIM, Yongin-si (KR); Jin Seon KWAK, Yongin-si (KR); Do Yeong PARK, Yongin-si (KR); Ji Hye LEE, Yongin-si (KR)

(21) Appl. No.: 18/643,229

(22) Filed: Apr. 23, 2024

(30) Foreign Application Priority Data
Jul. 31, 2023 (KR) 10-2023-0100054

(51) Int. Cl. H10K 59/80; G09G 3/3233; H10K 59/12; H10K 59/122

(52) U.S. Cl. CPC H10K 59/80515; G09G 3/3233; H10K 59/1201; H10K 59/122; G09G 2300/0819; G09G 2300/0842

(57) ABSTRACT

A pixel is disclosed that includes: a substrate; a pixel circuit disposed on the substrate and including at least one transistor and at least one capacitor; a first contact metal disposed on the substrate and to which a constant voltage is applied; an inorganic layer covering the first contact metal; a first pixel electrode disposed on the inorganic layer and electrically connected to the pixel circuit; a pixel defining film disposed on the first pixel electrode; a second contact metal disposed on the pixel defining film and electrically connected to the first contact metal; a separator disposed on the second contact metal; an organic light emitting portion disposed on the first pixel electrode; and a second pixel electrode disposed on the organic light emitting portion and connected to the second contact metal.

### CROSS-REFERENCE TO RELATED APPLICATION

This application claims priority to and the benefit of Korean Patent Application No. 10-2023-0100054 filed in the Korean Intellectual Property Office on Jul. 31, 2023, the entire contents of which are incorporated herein by reference.

### BACKGROUND

### (a) Field of the Invention

Embodiments of the present disclosure relate to a pixel, a manufacturing method thereof, and a display device including the same.

### (b) Description of the Related Art

As information technology has developed, importance of a display device, which is a connection medium between a user and information, has been highlighted. Accordingly, the use of display devices such as a liquid crystal display device, an organic light emitting display device, and the like has been increasing.

### SUMMARY

The present disclosure may provide a pixel that may improve visibility, a manufacturing method thereof, and a display device including the same.

The present disclosure may provide a pixel robust against noise, a manufacturing method thereof, and a display device including the same.

An embodiment of a pixel includes: a substrate; a pixel circuit disposed on the substrate and including at least one transistor and at least one capacitor; a first contact metal disposed on the substrate and to which a constant voltage is applied; an inorganic layer covering the first contact metal; a first pixel electrode disposed on the inorganic layer and electrically connected to the pixel circuit; a pixel defining film disposed on the first pixel electrode; a second contact metal disposed on the pixel defining film and electrically connected to the first contact metal; a separator disposed on the second contact metal; an organic light emitting portion disposed on the first pixel electrode; and a second pixel electrode disposed on the organic light emitting portion and connected to the second contact metal.

The constant voltage may be a low potential voltage.

The separator may have a reverse tapered shape.

The second contact metal may be connected to the first contact metal through a cathode contact hole formed by removing at least a portion of the pixel defining film and at least a portion of the inorganic layer.

A plurality of sub-pixels may be disposed on the substrate, and each of the plurality of sub-pixels may include the pixel circuit, the first pixel electrode may include a first anode electrode of a first sub-pixel among the plurality of sub-pixels; a second anode electrode of a second sub-pixel among the plurality of sub-pixels; and a third anode electrode of a third sub-pixel among the plurality of sub-pixels, and the pixel defining film may be disposed in a boundary area between the first anode electrode and the second anode electrode and a boundary area between the second anode electrode and the third anode electrode.

The first contact metal and the second contact metal may be disposed in the boundary area between the first anode electrode and the second anode electrode, and the boundary area between the second anode electrode and the third anode electrode.

The first contact metal and the second contact metal may be disposed in the boundary area between the first anode electrode and the second anode electrode, and may not be disposed in the boundary area between the second anode electrode and the third anode electrode.

The second contact metal may completely surround the first anode electrode.

The second contact metal may surround the first anode electrode, and at least a portion of the second contact metal may be open around the first anode electrode.

A width of an upper surface of the pixel defining film may be a first distance, a width of the second contact metal may be a second distance, and the second distance may be less than or equal to the first distance.

A width of the second contact metal may be a second distance, a width of a lower surface of the separator may be a third distance less than or equal to the second distance, and a width of an upper surface of the separator may be greater than or equal to the third distance.

The second pixel electrode may have a step of a size corresponding to a thickness of the second contact metal.

A lower end of the step may be disposed on the same plane as an upper surface of the second contact metal.

The pixel may further include a third contact metal disposed on the separator and connected to the second contact metal and the second pixel electrode.

The third contact metal may be connected to the second contact metal through a cathode contact hole formed by removing at least a portion of the separator.

An embodiment of a method of manufacturing a pixel includes: forming a first contact metal on a backplane substrate; forming an inorganic layer on the first contact metal; forming a first pixel electrode on the inorganic layer and electrically connecting the first pixel electrode and the backplane substrate; forming a pixel defining film on the first pixel electrode; forming a second contact metal on the pixel defining film, and electrically connecting the second contact metal and the first contact metal in an area in which at least a portion of the pixel defining film is removed; forming a separator on the second contact metal; forming an organic light emitting portion on the first pixel electrode and the separator; and forming a second pixel electrode on the organic light emitting portion and electrically connecting the second pixel electrode and the second contact metal.

The separator may be formed to have a reverse tapered shape.

The method of manufacturing the pixel may further include removing at least a portion of each of the separator and the organic light emitting portion to form a third contact metal connected to the second contact metal, wherein the second pixel electrode may be further connected to the third contact metal.

An embodiment of a display device includes: a plurality of pixels disposed on a substrate, each of which includes a pixel circuit; a plurality of scan lines disposed on the substrate and connected to the pixel circuits of the plurality of pixels; and a plurality of data lines disposed on the substrate and connected to the pixel circuits of the plurality of pixels, wherein at least one of the plurality of pixels includes a first contact metal disposed on the substrate and to which a constant voltage is applied; an inorganic layer at least partially covering the first contact metal; a first pixel electrode disposed on the inorganic layer and electrically connected to the pixel circuit; a pixel defining film disposed on the first pixel electrode; a second contact metal disposed on the pixel defining film and electrically connected to the first contact metal; a separator disposed on the second contact metal; an organic light emitting portion disposed on the first pixel electrode; and a second pixel electrode disposed on the organic light emitting portion and connected to the second contact metal.

The substrate may be a silicon substrate.

### BRIEF DESCRIPTION OF THE DRAWINGS

FIG. 1 illustrates a schematic top plan view of a display device according to embodiments of the present disclosure.

FIG. 2A, FIG. 2B, and FIG. 2C illustrate top plan views of embodiments of a pixel of FIG. 1.

FIG. 3 illustrates an equivalent circuit of sub-pixels included in the pixel of FIG. 2A to FIG. 2C.

FIG. 4 illustrates a cross-sectional view of an example of a light emitting element of FIG. 3.

FIG. 5 illustrates a cross-sectional view of another example of a light emitting element of FIG. 3.

FIG. 6 illustrates a cross-sectional view of a stacked structure of a pixel including a light emitting element of FIG. 3.

FIG. 7 illustrates a cross-sectional view taken along line A-A′ of the pixel of FIG. 2A to FIG. 2C according to an embodiment.

FIG. 8 illustrates a cross-sectional view taken along line A-A′ of the pixel of FIG. 2A to FIG. 2C according to another embodiment.

FIG. 9 illustrates a top view of a first sub-pixel of FIG. 8 based on FIG. 2A.

FIG. 10 illustrates an enlarged view of area “X” of FIG. 8.

FIG. 11 illustrates a cross-sectional view taken along line A-A′ of the pixel of FIG. 2A to FIG. 2C according to another embodiment.

FIG. 12 illustrates an enlarged view of area “Y” of FIG. 11.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals. Therefore, the above-mentioned reference numerals may be used in other drawings.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc. may be exaggerated for clarity.

In addition, the expression “equal to or the same as” in the description may mean “substantially equal to or the same as”. That is, it may be the same enough to convince those skilled in the art to be the same. Even other expressions may be expressions from which “substantially” is omitted.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the present disclosure. Singular forms are intended to include plural forms unless the context clearly indicates otherwise.

Terms such as “below”, “the lower side”, “the lower portion”, “on”, “the upper side”, and “the upper portion” are used to describe relationships or configurations of elements shown in the drawing. Such terms are understood to provide relative descriptions based on one or more directions shown in the drawing.

Unless otherwise defined, all terms (including technical and scientific terms) used herein have the same meaning as commonly understood by those skilled in the art to which this disclosure belongs. In addition, terms should be interpreted as having meanings consistent with their meaning in the context of the related art or as defined in commonly used dictionaries, unless as explicitly defined here. Further, the terms should not be limited to being interpreted in an ideal or overly formal sense.

It should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations thereof, in advance.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Hereinafter, embodiments of the present disclosure will be described in detail with reference to the accompanying drawings.

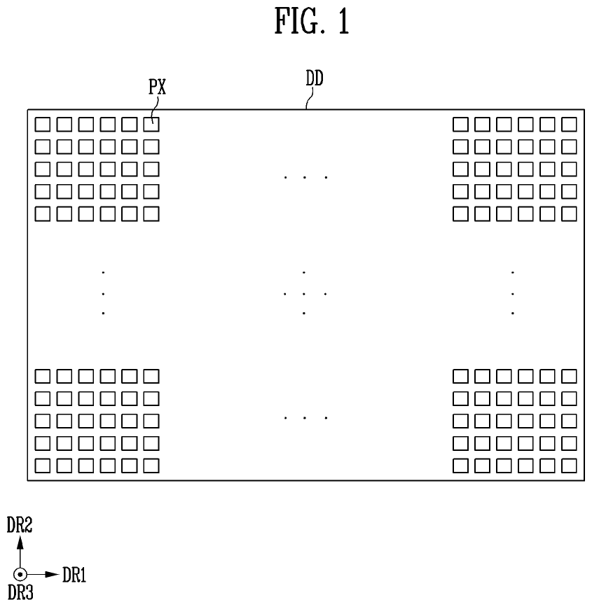

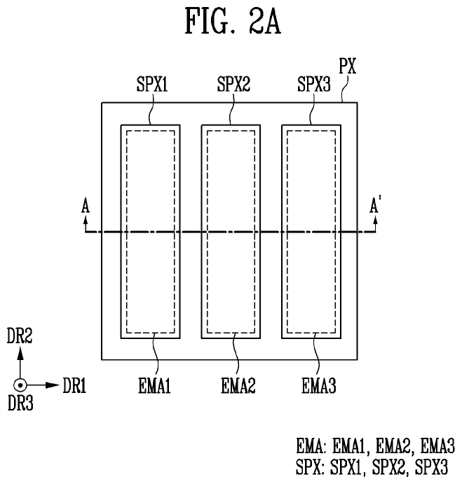

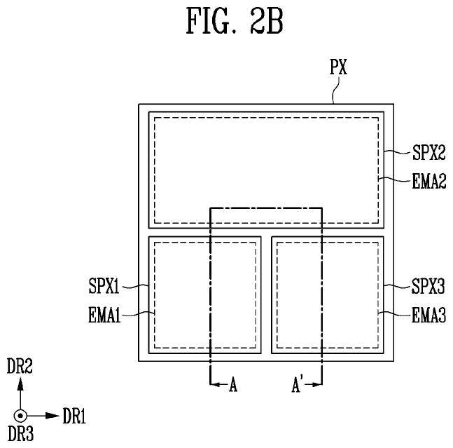

FIG. 1 illustrates a schematic top plan view of a display device DD according to embodiments of the present disclosure. FIG. 2A, FIG. 2B, and FIG. 2C illustrate top plan views of embodiments of a pixel PX of FIG. 1.

Referring to FIG. 1, the display device DD is a device for displaying a moving image or a still image, and may be used as a display screen of a portable electronic device such as a mobile phone, a smart phone, a tablet personal computer (PC), a smart watch, a watch phone, a mobile communication terminal, an electronic note, an electronic book, a portable multimedia players (PMP), a navigation device, and an ultra mobile PC (UMPC), and may be used as display screens of various products such as a television set, a laptop computer, a monitor, a billboard, an Internet of things (IoT) device.

The display device DD may be formed as a flat surface having a rectangular shape having a long side of a first direction DR1 and a short side of a second direction DR2 crossing the first direction DR1. A corner at which the long side of the first direction DR1 and the short side of the second direction DR2 meet may be rounded to have a predetermined curvature or may be formed to have a right angle. The flat shape of the display device DD is not limited to a quadrangular shape, and may be formed to have another polygonal, circular, or elliptical shape. The display device DD may be formed to be flat, but is not limited thereto. For example, the display device DD may include curved portions that are formed at left and right ends and have a constant curvature or a variable curvature. In addition, the display device DD may be flexibly formed to be bent, curved, folded, or rolled.

The display device DD may include a plurality of pixels PX configured to display an image (picture or video). The display device DD may further include a plurality of scan wires extending in the first direction DR1 and a plurality of data wires extending in the second direction DR2. In some embodiments, the pixels PX may be arranged in a matrix format in the first direction DR1 and the second direction DR2. However, embodiments of the present disclosure are not limited thereto, and the pixels PX may be arranged side by side in a diagonal direction different from the first direction DR1 and the second direction DR2.

The pixel PX may include two or more sub-pixels. Referring to FIG. 2A to FIG. 2C, the pixel PX may include a plurality of sub-pixels SPX1, SPX2, and SPX3. In FIG. 2A to FIG. 2C, an embodiment in which the pixel PX includes the first sub-pixel SPX1, the second sub-pixel SPX2, and the third sub-pixel SPX3 is shown as an example. However, the embodiments of the present disclosure are not limited thereto. For example, the pixel PX may include four or more sub-pixels. Below, for better understanding and ease of explanation, the case in which the pixel PX includes the first sub-pixel SPX1, the second sub-pixel SPX2, and the third sub-pixel SPX3 will be described as an example.

Each of the first sub-pixel SPX1, the second sub-pixel SPX2, and the third sub-pixel SPX3 may be connected (for example, electrically connected) to one of the plurality of data wires, and may be connected (for example, electrically connected) to at least one of the plurality of scan wires.

The sub-pixel may have a shape such as a polygon or a circle. Referring to FIG. 2A and FIG. 2B, each of the first sub-pixel SPX1, the second sub-pixel SPX2, and the third sub-pixel SPX3 may have a quadrangular planar shape of a rectangle, square, or rhombus. Referring to FIG. 2C, each of the first sub-pixel SPX1, the second sub-pixel SPX2, and the third sub-pixel SPX3 may have a planar shape other than a quadrangular planar shape, for example, a hexagonal planar shape. For example, referring to FIG. 2A, each of the first sub-pixel SPX1, the second sub-pixel SPX2, and the third sub-pixel SPX3 may have a rectangular planar shape having short sides in the first direction DR1 and long sides in the second direction DR2. For example, referring to FIG. 2B, at least one of the first sub-pixel SPX1, the second sub-pixel SPX2, and the third sub-pixel SPX3 (for example, the second sub-pixel SPX2) may have a rectangular planar shape having long sides in the first direction DR1 and short sides in the second direction DR2. For example, referring to FIG. 2B, the remainder of the first sub-pixel SPX1, the second sub-pixel SPX2, and the third sub-pixel SPX3 (for example, the first sub-pixel SPX1 or the third sub-pixel SPX3) may have a square planar shape. For example, referring to FIG. 2C, each of the first sub-pixel SPX1, the second sub-pixel SPX2, and the third sub-pixel SPX3 may have a hexagonal planar shape capable of densely filling a plane. Alternatively, in some embodiments, each of the first sub-pixel SPX1, the second sub-pixel SPX2, and the third sub-pixel SPX3 may also have a square or rhombus planar shape including sides having the same length in the first direction DR1 and the second direction DR2. However, embodiments of the present disclosure are not limited thereto, and at least one of the first sub-pixel SPX1, the second sub-pixel SPX2, and the third sub-pixel SPX3 may have a circular shape or a polygonal shape with rounded corners.

Referring to FIG. 2A, the first sub-pixel SPX1, the second sub-pixel SPX2, and the third sub-pixel SPX3 may be arranged in the first direction DR1. Referring to FIG. 2B, one of the second sub-pixel SPX2 and the third sub-pixel SPX3 (for example, the third sub-pixel SPX3) and the first sub-pixel SPX1 may be arranged in the first direction DR1, and the other thereof (for example, the second sub-pixel SPX2) and the first sub-pixel SPX1 may be arranged in the second direction DR2. One pixel PX including the first sub-pixel SPX1, the second sub-pixel SPX2, and the third sub-pixel SPX3 may have a planar shape close to a square (or substantially a square).

Alternatively, one of the first sub-pixel SPX1 and the third sub-pixel SPX3 and the second sub-pixel SPX2 may be arranged in the first direction DR1, and the other one thereof and the second sub-pixel SPX2 may be arranged in the second direction DR2. Alternatively, one of the first sub-pixel SPX1 and the second sub-pixel SPX2 and the third sub-pixel SPX3 may be arranged in the first direction DR1, and the other one thereof and the third sub-pixel SPX3 may be arranged in the second direction DR2.

Referring to FIG. 2C, one of the second sub-pixel SPX2 and the third sub-pixel SPX3 and the first sub-pixel SPX1 may be arranged in the first direction DR1, and the other one thereof and the first sub-pixel SPX1 may be arranged in a different direction from the first direction DR1 and the second direction DR2. For example, the first sub-pixel SPX1, the second sub-pixel SPX2, and the third sub-pixel SPX3 may be arranged in the form of an equilateral triangle.

The first sub-pixel SPX1 may emit light in a first wavelength band, the second sub-pixel SPX2 may emit light in a second wavelength band, and the third sub-pixel SPX3 may emit light in a third wavelength band. For example, light in the first wavelength band may be light in the red wavelength band. For example, light in the second wavelength band may be light in the blue wavelength band. For example, light in the third wavelength band may be light in the green wavelength band. The red wavelength band may be a wavelength band of about 600 nm (nanometer) to about 750 nm. The green wavelength band may be a wavelength band of about 480 nm to about 560 nm. The blue wavelength band may be a wavelength band of about 370 nm to about 460 nm. However, embodiments of the present disclosure are not limited thereto.

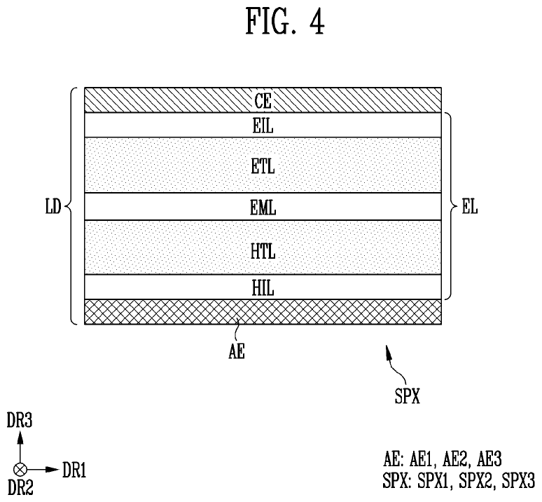

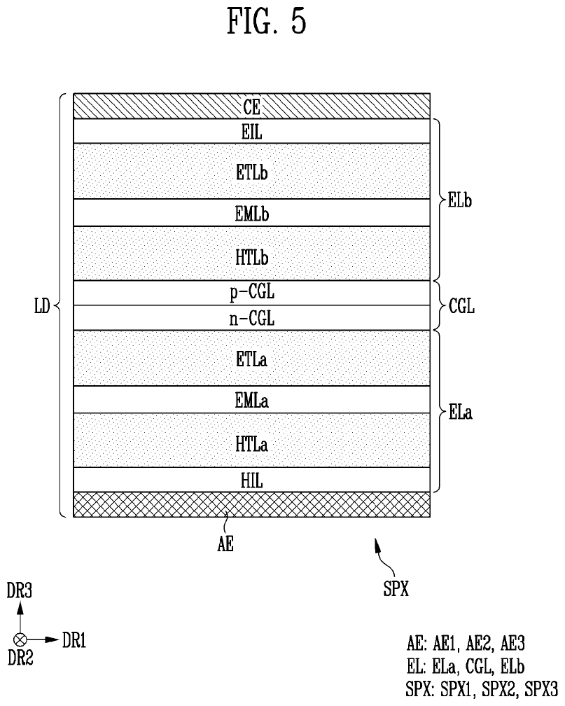

The sub-pixel SPX may include a light emitting element. For example, the first sub-pixel SPX1, the second sub-pixel SPX2, and the third sub-pixel SPX3 may include a light emitting element (for example, a light emitting element LD in FIG. 4 and FIG. 5) that emits light. The light emitting element may include an organic light emitting element having an organic layer.

The sub-pixel SPX may include a light emitting area EMA. The light emitting area EMA may correspond to an area in which the light emitting element is disposed. In some embodiments, a shape of the light emitting area EMA may be the same as, or similar to, the shape of the sub-pixel SPX. For example, referring to FIG. 2A and FIG. 2B, in the embodiment in which the shape of the sub-pixel SPX is a quadrangular shape, the shape of the light emitting area EMA may be the quadrangular shape, the same as the shape of the sub-pixel SPX. In some embodiments, the shape of the light emitting area EMA may be different from the shape of the sub-pixel SPX. For example, referring to FIG. 2C, in the embodiment in which the shape of the sub-pixel SPX is a hexagonal shape, the shape of the light emitting area EMA may be a circular shape, which is different from the shape of the sub-pixel SPX.

Referring to FIG. 2A to FIG. 2C, the first sub-pixel SPX1, the second sub-pixel SPX2, and the third sub-pixel SPX3 may have a first light emitting area EMA1, a second light emitting area EMA2, and a third light emitting area EMA3, respectively.

Referring to FIG. 2A, the shape of the first sub-pixel SPX1 may be a rectangular shape having a short side in the first direction DR1 and a long side in the second direction DR2. The shape of the first light emitting area EMA1 may be a rectangular shape with a short side in the first direction DR1 and a long side in the second direction DR2. The shape of the second sub-pixel SPX2 may be a rectangular shape with a short side in the first direction DR1 and a long side in the second direction DR2. The shape of the second light emitting area EMA2 may be a rectangular shape with a short side in the first direction DR1 and a long side in the second direction DR2. The shape of the third sub-pixel SPX3 may be a rectangular shape with a short side in the first direction DR1 and a long side in the second direction DR2. The shape of the third light emitting area EMA3 may be a rectangular shape with a short side in the first direction DR1 and a long side in the second direction DR2.

Referring to FIG. 2B, the shape of the first sub-pixel SPX1 may be a square shape with one side in the first direction DR1 and the other side in the second direction DR2. The shape of the first light emitting area EMA1 may be a square shape with one side in the first direction DR1 and the other side in the second direction DR2. The shape of the second sub-pixel SPX2 may be a rectangular shape with a long side in the first direction DR1 and a short side in the second direction DR2. The shape of the second light emitting area EMA2 may be a rectangular shape with a long side in the first direction DR1 and a short side in the second direction DR2. The shape of the third sub-pixel SPX3 may be a square shape with one side in the first direction DR1 and the other side in the second direction DR2. The shape of the third light emitting area EMA3 may be a square shape with one side in the first direction DR1 and the other side in the second direction DR2.

Referring to FIG. 2C, the shape of the first sub-pixel SPX1 may be a hexagonal shape (for example, a regular hexagonal shape) with one side in the second direction DR2. The shape of the first light emitting area EMA1 may be a circular shape. The shape of the second sub-pixel SPX2 may be a hexagonal shape (for example, a regular hexagonal shape) with one side in the second direction DR2. The shape of the second light emitting area EMA2 may be a circular shape. The shape of the third sub-pixel SPX3 may be a hexagonal shape (for example, a regular hexagonal shape) with one side in the second direction DR2. The shape of the third light emitting area EMA3 may be a circular shape.

An area of the first sub-pixel SPX1, an area of the second sub-pixel SPX2, and an area of the third sub-pixel SPX3 may be the same (or substantially the same), but embodiments of the present disclosure are not limited thereto. For example, at least one of the area of the first sub-pixel SPX1, the area of the second sub-pixel SPX2, and the area of the third sub-pixel SPX3 may be different from the others. Alternatively, two of the area of the first sub-pixel SPX1, the area of the second sub-pixel SPX2, and the area of the third sub-pixel SPX3 may be the same (or substantially the same), and the other one thereof may be different from the two. Alternatively, the area of the first sub-pixel SPX1, the area of the second sub-pixel SPX2, and the area of the third sub-pixel SPX3 may be different from each other.

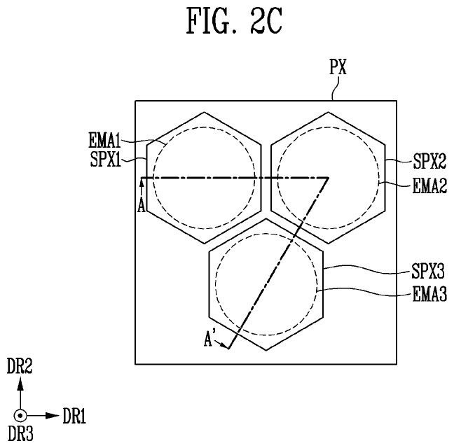

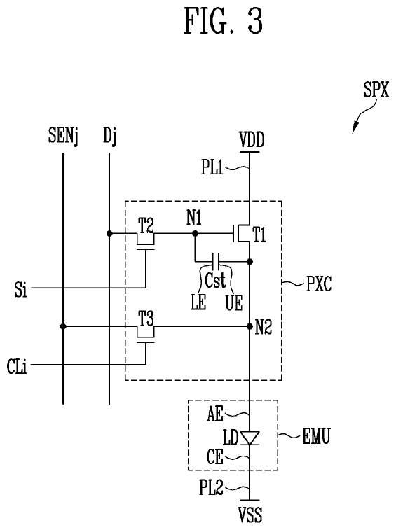

FIG. 3 illustrates an equivalent circuit of the sub-pixel SPX included in the pixel PX of FIG. 2A to FIG. 2C.

The sub-pixel SPX shown in FIG. 3 may be one of the sub-pixels SPX1, SPX2, and SPX3 shown in FIG. 2A to FIG. 2C.

In FIG. 3, for better understanding and ease of description, the sub-pixel SPX disposed in an i-th (i is an integer greater than or equal to 1) pixel row (or an i-th horizontal line) and a j-th (j is an integer greater than or equal to 1) pixel column will be described as an example.

Referring to FIG. 3, the sub-pixel SPX may include a light emitting portion EMU configured to emit light of luminance corresponding to a data signal. The sub-pixel SPX may include a pixel circuit PXC configured to drive the light emitting portion EMU.

The light emitting portion EMU may include a light emitting element LD. The light emitting element LD may be connected (for example, electrically connected) to a first power line PL1 to which a voltage of a first driving power source VDD (or a first power source VDD) is applied. The light emitting element LD may be connected (for example, electrically connected) to a second power line PL2 to which a voltage of a second driving power source VSS (or a second power source VSS) is applied.

The light emitting element LD may include a first pixel electrode AE and a second pixel electrode CE. The first pixel electrode AE may be one of an anode electrode and a cathode electrode (for example, the anode electrode), and the second pixel electrode CE may be the other of the anode electrode and the cathode electrode (for example, the cathode electrode). Referring to FIG. 3, the first pixel electrode AE may be connected to the first driving power source VDD via the pixel circuit PXC and the first power line PL1. The second pixel electrode CE may be connected to the second driving power source VSS via the second power line PL2. Hereinafter, for convenience of description, it is assumed that the first pixel electrode AE is an anode electrode of the light emitting element LD, and the second pixel electrode CE is a cathode electrode of the light emitting element LD. However, embodiments of the present disclosure are not limited thereto.

The first driving power source VDD and the second driving power source VSS may have different potentials. In this case, a potential difference between the first and second driving power sources VDD and VSS may be set to be equal to or higher than a threshold voltage of the light emitting element LD during a light emitting period of the sub-pixel SPX. The voltage of the first driving power source VDD may be a high potential voltage. The voltage of the second driving power source VSS may be a low-potential voltage.

Referring to FIG. 3, the pixel circuit PXC may be electrically connected to an i-th scan line Si and a j-th data line Dj. In some embodiments, the pixel circuit PXC may be electrically connected to a control line (for example, an i-th control line CLi). The pixel circuit PXC may be electrically connected to a sensing line (for example, a j-th sensing line SENj).

The pixel circuit PXC described above may include two or more transistors and at least one capacitor. For example, referring to FIG. 3, the pixel circuit PXC may include first, second, and third transistors T1, T2, and T3 and a storage capacitor Cst.

The first transistor T1 may be configured to control an amount of driving current applied to the light emitting element LD. The first transistor T1 may be referred to as a driving transistor. The first transistor T1 may be connected (for example, electrically connected) between the first driving power source VDD and the light emitting element LD. For example, a first terminal (one of a drain terminal and a source terminal) of the first transistor T1 may be electrically connected to the first driving power source VDD through the first power line PL1. A second terminal (the other one of the drain terminal and the source terminal) of the first transistor T1 may be connected (for example, electrically connected) to a second node N2. A gate electrode of the first transistor T1 may be connected (for example, electrically connected) to a first node N1. The first transistor T1 may control an amount of a current (for example, a driving current) applied to the light emitting element LD from the first driving power source VDD through the second node N2 according to a voltage applied to the first node N1. In some embodiments, the first terminal of the first transistor T1 may be a drain terminal, and the second terminal of the first transistor T1 may be a source terminal, but the embodiments of the present disclosure are not limited thereto. In some embodiments, the first terminal may be a source terminal and the second terminal may be a drain terminal.

The second transistor T2 may be configured to select the sub-pixel SPX and activate the sub-pixel SPX in response to a scan signal. The second transistor T2 may be referred to as a switching transistor. The second transistor T2 may switch electrical connection between the data line Dj and the first node N1. The second transistor T2 may be connected (for example, electrically connected) between the data line Dj and the first node N1. The first terminal of the second transistor T2 may be connected (for example, electrically connected) to the data line Dj. The second terminal of the second transistor T2 may be connected (for example, electrically connected) to the first node N1 (or the gate electrode of the first transistor T1). The gate electrode of the second transistor T2 may be connected (for example, electrically connected) to the scan line Si. The first terminal and the second terminal of the second transistor T2 are different terminals, and for example, when the first terminal is a drain terminal, the second terminal may be a source terminal.

The second transistor T2 may be turned on in response to a scan signal of a turn-on level voltage (for example, a high level voltage). When the second transistor T2 is turned on, the data line Dj and the first node N1 may be connected (for example, electrically connected). The first node N1 may be a point at which the second terminal of the second transistor T2 and the gate electrode of the first transistor T1 are connected. The second transistor T2 may transmit a data signal (for example, a data voltage) to the gate electrode of the first transistor T1.

The third transistor T3 may be configured to switch the electrical connection between the second node N2 and the sensing line SENj. The third transistor T3 may be connected (for example, electrically connected) between the first transistor T1 and the sensing line SENj. A sensing signal (for example, an analog voltage) may be obtained through the sensing line SENj. When the third transistor T3 is turned on, the voltage of the second node N2 may be initialized. The third transistor T3 is also referred to as an initialization transistor. The third transistor T3 may be turned on in response to a sensing control signal of the turn-on level voltage from the control line CLi. When the third transistor T3 is turned on, the initialization voltage applied to the sensing line SELj may be transmitted to the second node N2. The third transistor T3 may include a first terminal that is connected (for example, electrically connected) to the second node N2. The third transistor T3 may include a second terminal connected (for example, electrically connected) to the sensing line SENj. The third transistor T3 may include a gate electrode connected (for example, electrically connected) to the control line CLi. The first terminal and the second terminal of the third transistor T3 are different terminals, and for example, the first terminal may be one of a drain terminal and a source terminal, and the second terminal may be the other of the drain terminal and the source terminal.

The sensing signal may reflect a characteristic value (for example, a characteristic value of the first transistor T1 or a characteristic value of the light emitting element LD) of the sub-pixel SPX or a change in the characteristic value. In some embodiments, a characteristic value (for example, a threshold voltage, mobility, and the like) of the first transistor T1 or a change thereof may be detected based on the sensing signal. In some embodiments, a characteristic value (for example, a threshold voltage) of the light emitting element LD or a change thereof may be detected based on the sensing signal. The sensing signal may be used to compensate for the deviation of characteristic values between the plurality of sub-pixels SPX.

The storage capacitor Cst may be configured to maintain a voltage difference between the first node N1 and the second node N2. Referring to FIG. 3, the storage capacitor Cst may include a first electrode LE (or a first storage electrode) and a second electrode UE (or a second storage electrode). The first electrode LE may be electrically connected to the first node N1. The second electrode UE may be electrically connected to the second node N2. The storage capacitor Cst may be charged with a data signal or a voltage corresponding thereto to function to maintain the voltage difference between the first node N1 and the second node N2 during one frame period. For example, the storage capacitor Cst may store a voltage corresponding to a difference between a voltage of the gate electrode of the first transistor T1 and a voltage of the second node N2.

Each of the transistors configuring the pixel circuit PXC may be implemented as an N-type transistor or a P-type transistor. In the N-type transistor, the turn-on level voltage may be a high level voltage and the turn-off level voltage may be a low level voltage. In the P-type transistor, the turn-on level voltage may be a low level voltage and the turn-off level voltage may be a high level voltage. For example, referring to FIG. 3, an embodiment is disclosed in which the first to third transistors T1 to T3 configuring the pixel circuit PXC are all N-type transistors. However, embodiments of the present disclosure are not limited thereto. For example, at least one of the first to third transistors T1 to T3 described above may be implemented as a P-type transistor.

In some embodiments, the structure of the pixel circuit PXC may be variously changed. For example, referring to FIG. 3, an embodiment of the pixel circuit PXC is shown including three transistors T1 to T3 and one storage capacitor Cst. However, embodiments of the present disclosure are not limited thereto. For example, the pixel circuit PXC may contain four or more transistors, or two or more capacitors.

FIG. 4 illustrates a cross-sectional view of an example of the light emitting element LD of FIG. 3.

Referring to FIG. 4, the light emitting element LD may include a first pixel electrode AE, an organic light emitting portion EL, and a second pixel electrode CE. In some embodiments, the first pixel electrode AE, the organic light emitting portion EL, and the second pixel electrode CE may be sequentially stacked.

In the embodiment, the first pixel electrode AE may be formed (for example, patterned) corresponding to the first to third sub-pixels SPX1 to SPX3. In the example, the first pixel electrode AE may include first to third anode electrodes AE1 to AE3 corresponding to the first to third sub-pixels SPX1-SPX3, respectively. The first anode electrode AE1 may be the first pixel electrode AE corresponding to the first sub-pixel SPX1. The second anode electrode AE2 may be the first pixel electrode AE corresponding to the second sub-pixel SPX2. The third anode electrode AE3 may be the first pixel electrode AE corresponding to the third sub-pixel SPX3.

The organic light emitting portion EL may be disposed (for example, formed) on the first pixel electrode AE. The organic light emitting portion EL may include one or more light generation layers.

In some embodiments, the organic light emitting portion EL may have a multi-layered thin film structure including a plurality of light generation layers. For example, the organic light emitting portion EL may include a hole injection layer HIL, a hole transport layer HTL, an organic light emitting layer EML, an electron transport layer ETL, and an electron injection layer EIL. For example, the hole injection layer HIL, the hole transport layer HTL, the organic light emitting layer EML, the electron transport layer ETL, and the electron injection layer EIL may be sequentially stacked.

The hole injection layer HIL may be configured to smoothly inject holes from the first pixel electrode AE into the organic light emitting layer EML. The hole injection layer HIL may be placed between the first pixel electrode AE and the hole transport layer HTL. The hole injection layer HIL may be configured as an organic layer including an organic material.

The hole transport layer HTL may be disposed between the hole injection layer HIL and the organic light emitting layer EML. The hole transport layer HTL may be configured to transport holes provided from the first pixel electrode AE to the organic light emitting layer EML. The electron injection layer EIL may be configured to smoothly inject electrons from the second pixel electrode CE to the organic light emitting layer EML. The electron injection layer EIL may be disposed between the second pixel electrode CE and the electron transport layer ETL.

The electron transport layer ETL may be disposed between the electron injection layer EIL and the organic light emitting layer EML. The electron transport layer ETL may be configured to transport electrons provided from the second pixel electrode CE to the organic light emitting layer EML.

The organic light emitting layer EML is an area in which light is generated by a recombination of holes and electrons. The organic light emitting layer EML may include an organic light emitting material configured to emit light in a predetermined wavelength band. The organic light emitting materials may include, for example, a high molecular organic material or a low molecular organic material. For example, the organic light emitting layer EML may include an organic material that emits blue light. However, embodiments of the present disclosure are not limited thereto. For example, the organic light emitting layer EML may include an organic material configured to emit light in a red wavelength band or light in a green wavelength band. In some embodiments, the organic light emitting layer EML may include inorganic materials or quantum dots.

In some embodiments, the second pixel electrode CE may be integrally provided (for example, formed). The second pixel electrode CE may be disposed on the organic light emitting portion EL. The second pixel electrode CE may be integrally formed in a plurality of light emitting elements.

FIG. 5 illustrates a cross-sectional view of another example of the light emitting element LD of FIG. 3.

Referring to FIG. 5, the light emitting element LD may include a first pixel electrode AE, an organic light emitting portion EL, and a second pixel electrode CE. The organic light emitting portion EL may be formed by stacking two or more organic light emitting portions. For example, referring to FIG. 5, the organic light emitting portion EL may be formed by stacking a first organic light emitting portion ELa and a second organic light emitting portion ELb.

The organic light emitting portion EL may include one or more light generation layers. For example, the organic light emitting portion EL may include a plurality of light generation layers. In some embodiments, the organic light emitting portion EL may include the first organic light emitting portion ELa, a charge generation layer CGL, and the second organic light emitting portion ELb. Referring to FIG. 5, the first pixel electrode AE, the first organic light emitting portion ELa, the charge generation layer CGL, the second organic light emitting portion ELb, and the second pixel electrode CE may be sequentially stacked.

The first organic light emitting portion ELa may include the hole injection layer HIL, a first hole transport layer HTLa, a first organic light emitting layer EMLa, and a first electron transport layer ETLa. The hole injection layer HIL, the first hole transport layer HTLa, the first organic light emitting layer EMLa, and the first electron transport layer ETLa may be sequentially stacked.

The second organic light emitting portion ELb may include a second hole transport layer HTLb, a second organic light emitting layer EMLb, a second electron transport layer ETLb, and the electron injection layer EIL. The second hole transport layer HTLb, the second organic light emitting layer EMLb, the second electron transport layer ETLb, and the electron injection layer EIL may be sequentially stacked.

In some embodiments, a buffer layer (not shown) may be disposed on the first organic light emitting layer EMLa and the second organic light emitting layer EMLb. The buffer layer may include a compound with electron transport properties.

The charge generation layer CGL may serve to supply charges to the first organic light emitting portion ELa and the second organic light emitting portion ELb. The charge generation layer CGL may include an n-type charge generation layer n-CGL and a p-type charge generating layer p-CGL.

The n-type charge generation layer n-CGL may be configured to supply electrons to the first organic light emitting portion ELa. For example, the n-type charge generation layer n-CGL may include a metallic material as a dopant.

The p-type charge generation layer p-CGL may be configured to supply holes to the second organic light emitting portion ELb.

In FIG. 5, the organic light emitting portion EL is shown as being formed by stacking the first organic light emitting portion ELa and the second organic light emitting portion ELb, but embodiments of the present disclosure are not limited thereto. For example, the organic light emitting portion EL may be formed by stacking three or more organic light emitting portions.

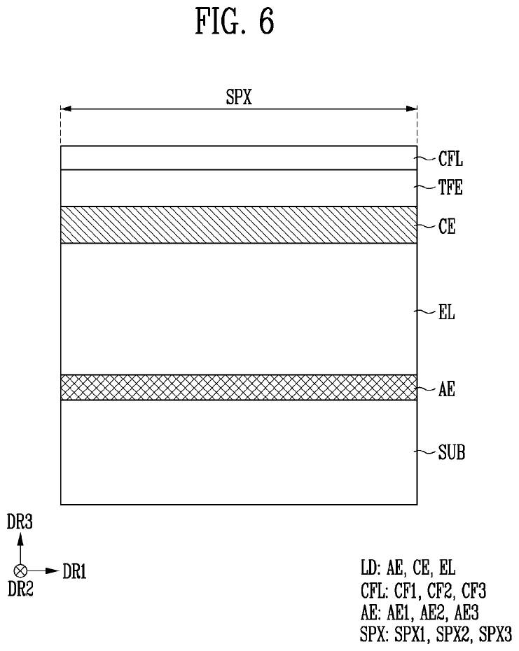

FIG. 6 illustrates a cross-sectional view of a stacked structure of the pixel PX including the light emitting element LD of FIG. 3.

Referring to FIG. 6, the pixel PX may include a substrate SUB, the light emitting element LD, an encapsulation layer TFE, and a color filter layer CFL.

The substrate SUB may be implemented as a glass substrate, a plastic substrate, or a silicon substrate. The transistor and the capacitor of the above-described pixel circuit PXC (see FIG. 3) may be formed on the substrate SUB. The substrate SUB on which the pixel circuit PXC is formed may be referred to as a backplane substrate. Hereinafter, for better understanding and ease of description, the backplane substrate is referred to as the substrate SUB, but embodiments of the present disclosure are not limited thereto.

A pixel circuit layer may be formed (for example, patterned) on the substrate SUB. The pixel circuit layer may include various circuit elements and wires for driving the light emitting element LD. For example, in the pixel circuit layer, a plurality of transistors (for example, the first to third transistors T1 to T3 (see FIG. 3)), the storage capacitor Cst (see FIG. 3), the scan line Si (see FIG. 3), the data line Dj (see FIG. 3), the first power line PL1 (see FIG. 3), the second power line PL2 (see FIG. 3), and the like may be disposed. However, embodiments of the present disclosure are not limited thereto.

The light emitting element LD may be placed on the substrate SUB. The light emitting element LD may include the first pixel electrode AE, the organic light emitting portion EL, and the second pixel electrode CE.

The first pixel electrode AE may be formed (for example, patterned) corresponding to the first to third sub-pixels SPX1 to SPX3. For example, the first pixel electrode AE may be patterned into a first anode electrode AE1, a second anode electrode AE2, and a third anode electrode AE3, and the patterned first to third anode electrodes AE1 to AE3 may correspond to the first to third sub-pixels SPX1 to SPX3, respectively. For example, the first pixel electrode AE may include a light-transmissive conductive material with a high work function. For example, the first pixel electrode AE may include a light-transmissive (for example, transparent) conductive material such as a tin oxide (TO), a zinc oxide (ZnO), an indium tin oxide (ITO), an indium zinc oxide (IZO), an indium tin zinc oxide (ITZO), and an indium gallium zinc oxide (IGZO). However, embodiments of the present disclosure are not limited thereto.

The organic light emitting portion EL may be disposed between the first pixel electrode AE and the second pixel electrode CE. The organic light emitting portion EL may emit light by a recombination of a hole supplied from the first pixel electrode AE and an electron supplied from the second pixel electrode CE. The organic light emitting portion EL may be, for example, a white light emitting layer that emits white light. In some embodiments, the organic light emitting portion EL may be, for example, a blue light emitting layer that emits blue light. In some embodiments, the light (for example, white light) emitted from the organic light emitting portion EL may be converted into one of red wavelength band light, green wavelength band light, and blue wavelength band light by the color filter layer CFL. The internal design of the organic light emitting portion EL may also vary depending on the color of light to be realized. In some embodiments, the organic light emitting portion EL may include a blue light emitting layer, and may emit light in a blue wavelength band. In some embodiments, the organic light emitting portion EL may include a green light emitting layer, and may emit light in a green wavelength band. In some embodiments, the organic light emitting portion EL may include a red light emitting layer, and may emit light in a red wavelength band.

The second pixel electrode CE may be disposed on the organic light emitting portion EL. The second pixel electrode CE may be formed entirely on the substrate SUB, and may be formed as one layer. The second pixel electrodes CE of the first to third sub-pixels SPX1 to SPX3 may be connected to each other to be formed as one body. For example, the second pixel electrode CE may include a conductive material with a low work function. For example, the second pixel electrode CE may include a light-transmissive conductive material such as a tin oxide (TO), a zinc oxide (ZnO), an indium tin oxide (ITO), an indium zinc oxide (IZO), an indium tin zinc oxide (ITZO), and an indium gallium zinc oxide (IGZO), and an alloy of ytterbium (Yb). For example, the second pixel electrode CE may include a metallic material such as silver (Ag) and copper (Cu), and a magnesium-silver (Mg—Ag) alloy. The second pixel electrode CE may be formed by thinly disposing a metallic material, an alloy, and the like, but is not limited thereto.

The encapsulation layer TFE may be disposed on the second pixel electrode CE. The encapsulation layer TFE may be configured to protect the light emitting element LD by blocking moisture or oxygen flowing in from the outside. The encapsulation layer TFE may be implemented as a multi-layered film in which one or more inorganic films and one or more organic films are alternately disposed.

The color filter layer CFL may be disposed on the encapsulation layer TFE. The color filter layer CFL may be configured to convert light (for example, light in a white wavelength band) emitted from the organic light emitting portion EL of the light emitting element LD into light of a specific color. The color filter layer CFL may include first, second, and third color filters CF1, CF2, and CF3, which are disposed to correspond to the first, second, and third sub-pixels SPX1, SPX2, and SPX3, respectively.

The first color filter CF1 may be disposed in an area corresponding to the first anode electrode AE1 (for example, an area overlapping with the first anode electrode AE1 in the third direction DR3). For example, the first color filter CF1 may selectively transmit light in the first wavelength band. For example, the first color filter CF1 may include a color filter material of the first color that transmits light in the first wavelength band and blocks light in the second and third wavelength bands.

The second color filter CF2 may be disposed in an area corresponding to the second anode electrode AE2 (for example, an area overlapping with the second anode electrode AE2 in the third direction DR3). For example, the second color filter CF2 may selectively transmit light in the second wavelength band. For example, the second color filter CF2 may include a color filter material of the second color that transmits light in the second wavelength band and blocks light in the first and third wavelength bands.

The third color filter CF3 may be disposed in an area corresponding to the third anode electrode AE3 (for example, an area overlapping with the third anode electrode AE3 in the third direction DR3). For example, the third color filter CF3 may selectively transmit light in the third wavelength band. For example, the third color filter CF3 may include a color filter material of the third color that transmits light in the third wavelength band and blocks light in the first and second wavelength bands.

In the embodiment, when the first sub-pixel SPX1 is a red sub-pixel, the first color filter CF1 may include a red color filter material. When the second sub-pixel SPX2 is a green sub-pixel, the second color filter CF2 may include a green color filter material. When the third sub-pixel SPX3 is a blue sub-pixel, the third color filter CF3 may include a blue color filter material.

In some embodiments, the color filter CF may be omitted. For example, in an embodiment in which light in the first wavelength band (for example, a red wavelength band) is emitted from the organic light emitting portion EL corresponding to the first sub-pixel SPX1, light in the second wavelength band (for example, a blue wavelength band) is emitted from the organic light emitting portion EL corresponding to the second sub-pixel SPX2, and light in the third wavelength band (for example, a green wavelength band) is emitted from the organic light emitting portion EL corresponding to the third sub-pixel SPX3, the color filter CF may be omitted.

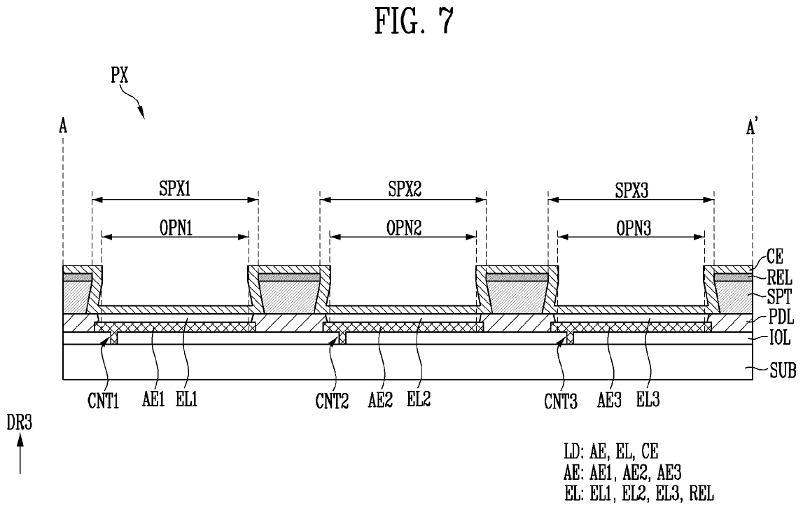

FIG. 7 illustrates a cross-sectional view taken along line A-A′ of the pixel PX of FIG. 2A to FIG. 2C according to an embodiment.

Referring to FIG. 7, the pixel PX may include a substrate SUB, an inorganic layer IOL, a first pixel electrode AE, an organic light emitting portion EL, a second pixel electrode CE, a pixel defining film PDL, and a separator SPT.

The inorganic layer IOL may be disposed on the substrate SUB. Referring to FIG. 7, the inorganic layer IOL may be disposed entirely on the substrate SUB. The inorganic layer IOL may be disposed between the substrate SUB and the light emitting element LD. The inorganic layer IOL may serve as a cavity control layer that amplifies the light emitted from the organic light emitting portion EL and improves luminous efficiency. For example, the inorganic layer IOL may be formed in a structure to implement a micro cavity effect. Referring to FIG. 7, the inorganic layer IOL is shown to have a uniform thickness on the substrate SUB. However, embodiments of the present disclosure are not limited thereto. For example, in order for the first to third sub-pixels SPX1 to SPX3 to realize a micro cavity effect in response to the wavelength of light emitted from the corresponding sub-pixel, the thickness of the inorganic layer IOL may be different for the first to third sub-pixels SPX1 to SPX3.

The first pixel electrode AE may be disposed on the inorganic layer IOL. The first pixel electrode AE may include first to third anode electrodes AE1 to AE3 corresponding to the first to third sub-pixels SPX1 to SPX3. Referring to FIG. 7, the first to third anode electrodes AE1 to AE3 may be disposed to be spaced apart from each other in the first direction DR1. The first, second, and third anode electrodes AE1, AE2, and AE3 may be connected (for example, electrically connected) to the substrate SUB through first, second, and third contact holes CNT1, CNT2, and CNT3, respectively. The first to third contact holes CNT1 to CNT3 may be formed in the inorganic layer IOL.

The pixel defining film PDL may be disposed on the first pixel electrode AE. The pixel defining film PDL may be configured to distinguish the first to third sub-pixels SPX1 to SPX3 from each other. The pixel defining film PDL may define a position at which the organic light emitting portion EL is disposed. The pixel defining film PDL may include openings to expose at least a portion of the first pixel electrode AE. For example, referring to FIG. 7, the pixel defining film PDL may include first, second, and third openings OPN1, OPN2, and OPN3 configured to expose at least a portion of each of the first, second, and third anode electrodes AE1, AE2, and AE3. The first to third openings OPN1 to OPN3 may correspond to light emitting areas in which light is respectively emitted from the first to third sub-pixels SPX1 to SPX3. The first opening OPN1 may expose at least a portion of the first anode electrode AE1. The second opening OPN2 may expose at least a portion of the second anode electrode AE2. The third opening OPN3 may expose at least a portion of the third anode electrode AE3.

The pixel defining film PDL may include an inorganic material. For example, the pixel defining film PDL may include one or more of a silicon oxide (SiOₓ) and a silicon nitride (SiNₓ). In some embodiments, the pixel defining film PDL may have a multi-layered structure in which a layer containing a silicon oxide (SiOₓ) and a layer containing a silicon nitride (SiNₓ) are stacked. However, the present disclosure is not limited thereto. In another embodiment, the pixel defining film PDL may include an organic material. For example, the pixel defining film PDL may include one or more of an acrylic resin, an epoxy resin, a phenol resin, a polyamide resin, and a polyimide resin.

The separator SPT may be disposed on the pixel defining film PDL. In some embodiments, the separator SPT may have a reverse tapered shape in which a width gradually increases toward an upper side. The separator SPT may separate the organic light emitting portion EL, which is commonly disposed in the first to third sub-pixels SPX1 to SPX3, corresponding to respective sub-pixels. Accordingly, the lateral leakage phenomenon between adjacent sub-pixels may be improved by the organic light emitting portion EL commonly disposed in the first to third sub-pixels SPX1 to SPX3. Accordingly, deterioration of luminance or color purity of the display device DD (see FIG. 1) may be prevented. The separator SPT may include an inorganic material. For example, the separator SPT may include one or more of silicon oxide (SiOₓ) and a silicon nitride (SiNₓ). In some embodiments, the separator SPT may have a multi-layered structure in which a layer containing a silicon oxide (SiOₓ) and a layer containing a silicon nitride (SiNₓ) are stacked. However, the present disclosure is not limited thereto. In another embodiment, the separator SPT may include an organic material. For example, the separator SPT may include one or more of an acrylic resin, an epoxy resin, a phenol resin, a polyamide resin, and a polyimide resin.

The organic light emitting portion EL may be disposed on the first pixel electrode AE and the pixel defining film PDL. The organic light emitting portion EL may be divided into a plurality of light emitting portions by being cut off from each other by the pixel defining film PDL and the separator SPT. The organic light emitting portion EL may be divided into a first light emitting portion EL1, a second light emitting portion EL2, a third light emitting portion EL3, and a remaining light emitting portion REL by the pixel defining film PDL and the separator SPT. In some embodiments, a plurality of light generation layers included in the organic light emitting portion EL may be disposed to be separated by the pixel defining film PDL and the separator SPT, respectively. However, embodiments of the present disclosure are not limited thereto. In some embodiments, at least some of the plurality of light generation layers included in the organic light emitting portion EL may be connected (for example, continuously extended) in the first to third sub-pixels SPX1 to SPX3, and the remaining some of the plurality of light generation layers may be separated (for example, cut off) by the pixel defining film PDL and the separator SPT. For example, among the plurality of light generation layers configuring the organic light emitting portion EL, the hole injection layer HIL (see FIG. 4 and FIG. 5) or the charge generation layer CGL (see FIG. 5) may be separated by the pixel defining film PDL and the separator SPT.

At least a portion of the organic light emitting portion EL may be disposed in an area surrounded by the pixel defining film PDL or the separator SPT. Referring to FIG. 7, the first light emitting portion EL1 may be surrounded by the pixel defining film PDL or the separator SPT to form the first sub-pixel SPX1. The second light emitting portion EL2 may be surrounded by the pixel defining film PDL or the separator SPT to form the second sub-pixel SPX2. The third light emitting portion EL3 may be surrounded by the pixel defining film PDL or the separator SPT to form the third sub-pixel SPX3.

The remaining portion of the organic light emitting portion EL may be disposed on the pixel defining film PDL or the separator SPT. Referring to FIG. 7, the remaining light emitting portion REL may be disposed on the separator SPT. The remaining light emitting portion REL may be separated from the first to third light emitting portions EL1 to EL3 by the separator SPT.

Referring to FIG. 7, the upper surfaces of the first to third light emitting portions EL1 to EL3 may be disposed on substantially the same plane as the upper surface of the pixel defining film PDL. For example, on a plane defined by the first direction DR1 and the second direction DR2, both the upper surface of the pixel defining film PDL and the upper surfaces of the first to third light emitting portions EL1 to EL3 may be disposed.

The separator SPT may be disposed in a boundary area between adjacent light emitting portions (for example, light emitting portions adjacent to each other in the first direction DR1) or adjacent sub-pixels (for example, sub-pixels adjacent to each other in the first direction DR1). Referring to FIG. 7, the separator SPT may be disposed in a boundary area between the first light emitting portion EL1 and the second light emitting portion EL2 or a boundary area between the first sub-pixel SPX1 and the second sub-pixel SPX2. The separator SPT may be disposed in a boundary area between the second light emitting portion EL2 and the third light emitting portion EL3 or a boundary area between the second sub-pixel SPX2 and the third sub-pixel SPX3.

The second pixel electrode CE may be disposed on the organic light emitting portion EL. For example, the second pixel electrode CE may be disposed (or formed) in one layer as a whole on the organic light emitting portion EL. The second pixel electrode CE may be disposed according to the profile of the first to third light emitting portion EL1 to EL3 and the separator SPT. In some embodiments, all of the plurality of light generation layers configuring the organic light emitting portion EL may be separated by the separator SPT, and the second pixel electrode CE may contact at least a portion of the separator SPT (for example, a side surface of the separator SPT).

In some embodiments, a reflective electrode (not shown) may be further disposed on the substrate SUB. The reflective electrode may be placed between the substrate SUB and the first pixel electrode AE. The reflective electrode may be configured to reflect light emitted from the organic light emitting portion EL to the upper surface (for example, the third direction DR3). The reflective electrode may include a metallic material with excellent reflectivity. Accordingly, visibility may be improved. The reflective electrode may include, for example, aluminum (Al), silver (Ag), a silver (Ag) alloy, copper (Cu), a magnesium-silver (Mg—Ag) alloy, and the like, but embodiments of the present disclosure are not limited thereto.

Referring to FIG. 7, the separator SPT may have an inverse tapered shape. Accordingly, a problem may occur in which the second pixel electrode CE is disconnected at a boundary area between the sub-pixels. As a result, the display quality may be deteriorated.

In some embodiments, as a plurality of pixels PX are integrated at high density in the display device DD (see FIG. 1), interference may occur between adjacent sub-pixels. For example, the substrate SUB may be a silicon substrate, and the width of the first to third openings OPN1 to OPN3 may be about 3 μm (micrometer) or less. Due to the voltage applied to the first anode electrode AE1, interference (for example, interference by parasitic capacitance) may occur in the second anode electrode AE2 adjacent thereto. Due to the voltage applied to the second anode electrode AE2, interference (for example, interference by parasitic capacitance) may occur in the third anode electrode AE3 adjacent thereto. Due to the influence of interference, a current may flow in adjacent sub-pixels. As a result, the problem of color mixing may occur.

A method is required to solve the problem of disconnection of the second pixel electrode CE and the problem of interference between adjacent sub-pixels.

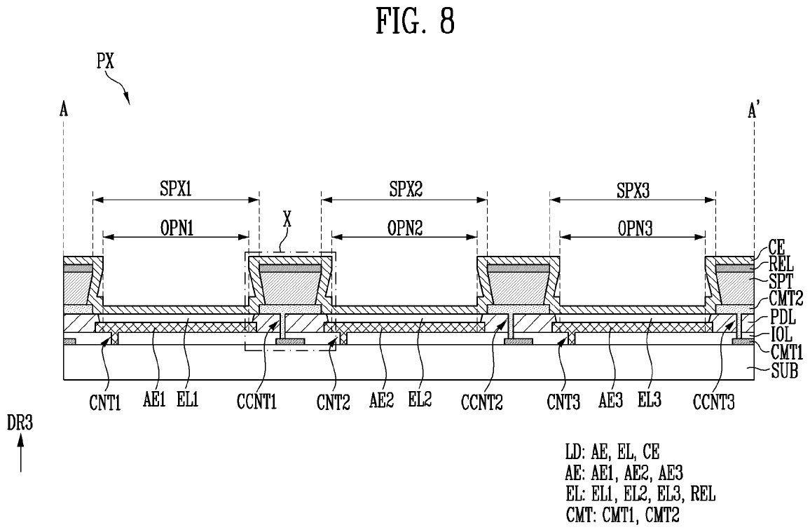

FIG. 8 illustrates a cross-sectional view taken along line A-A′ of the pixel PX of FIG. 2A to FIG. 2C according to another embodiment.

Referring to FIG. 8, the pixel PX may include a substrate SUB, a first contact metal CMT1, an inorganic layer IOL, a first pixel electrode AE, a pixel defining film PDL, a second contact metal CMT2, a separator SPT, an organic light emitting portion EL, and a second pixel electrode CE.

The first contact metal CMT1, the inorganic layer IOL, the first pixel electrode AE, the pixel defining film PDL, the second contact metal CMT2, the separator SPT, the organic light emitting portion EL, and the second pixel electrode CE may be sequentially formed.

In some embodiments, the first contact metal CMT1 may be formed on the substrate SUB (or a backplane substrate). For example, the first contact metal CMT1 may be formed with the pixel circuit PXC (see FIG. 3). For example, the first contact metal CMT1 may be formed between the pixel circuit PXC and the inorganic layer IOL. Hereinafter, for convenience of description, an embodiment in which the first contact metal CMT1 is formed on the backplane substrate is described as an example, but embodiments of the present disclosure are not limited thereto.

A constant voltage may be applied to the first contact metal CMT1. For example, the voltage of the second driving power source VSS may be applied to the first contact metal CMT1. In some embodiments, the first contact metal CMT1 may receive the voltage of the second driving power source VSS from the substrate SUB. In some embodiments, the first contact metal CMT1 may be grounded.

The first contact metal CMT1 may be formed to have a single-layered or multi-layered structure.

The first contact metal CMT1 may be disposed under the pixel defining film PDL. For example, the first contact metal CMT1 may overlap at least a portion of the pixel defining film PDL (for example, overlap with at least a portion of the pixel defining film PDL in the third direction DR3). The first contact metal CMT1 may be adjacent (for example, adjacent in the first direction DR1) to the first to third contact holes CNT1 to CNT3.

The width of the first contact metal CMT1 (for example, the width in the first direction DR1) is shown to be smaller than the width of the pixel defining film PDL in the same direction. However, embodiments of the present disclosure are not limited thereto. In some embodiments, the width of the first contact metal CMT1 may be equal to or greater than the width of the pixel defining film PDL.

Referring to FIG. 8, an embodiment in which the first contact metal CMT1 is disposed below all the separators SPT is shown. However, the embodiments of the present disclosure are not limited thereto, and the first contact metal CMT1 may be disposed below at least a portion of the separator SPT, and the first contact metal CMT1 may not be disposed below the remaining portion of the separator SPT. For example, the first contact metal CMT1 may be disposed below the separator SPT disposed in the boundary area between the first sub-pixel SPX1 and the second sub-pixel SPX2, and the first contact metal CMT1 may not be disposed below the separator SPT disposed in the boundary area between the second sub-pixel SPX2 and the third sub-pixel SPX3. For example, the first contact metal CMT1 may not be disposed below the separator SPT disposed in the boundary area between the first sub-pixel SPX1 and the second sub-pixel SPX2, and the first contact metal CMT1 may be disposed below the separator SPT disposed in the boundary area between the second sub-pixel SPX2 and the third sub-pixel SPX3.

The inorganic layer IOL may be formed while covering the first contact metal CMT1. The inorganic layer IOL may be disposed between the first contact metal CMT1 and the pixel defining film PDL.

The second contact metal CMT2 may be formed on the pixel defining film PDL. The second contact metal CMT2 may be disposed between the pixel defining film PDL and the separator SPT. The second contact metal CMT2 may be connected (for example, electrically connected) to the first contact metal CMT1. Referring to FIG. 8, the second contact metal CMT2 may be connected (for example, electrically connected) to the first contact metal CMT1 through first, second, and third cathode contact holes CCNT1, CCNT2, and CCNT3.

Referring to FIG. 8, an embodiment in which the second contact metal CMT2 is disposed below all the separators SPT is shown. However, the embodiments of the present disclosure are not limited thereto, and the second contact metal CMT2 may be disposed below at least a portion of the separator SPT, and the second contact metal CMT2 may not be disposed below the remaining portion of the separator SPT. For example, the second contact metal CMT2 may be disposed below the separator SPT disposed in the boundary area between the first sub-pixel SPX1 and the second sub-pixel SPX2, and the second contact metal CMT2 may not be disposed below the separator SPT disposed in the boundary area between the second sub-pixel SPX2 and the third sub-pixel SPX3. For example, the second contact metal CMT2 may not be disposed below the separator SPT disposed in the boundary area between the first sub-pixel SPX1 and the second sub-pixel SPX2, and the second contact metal CMT2 may be disposed below the separator SPT disposed in the boundary area between the second sub-pixel SPX2 and the third sub-pixel SPX3.

The cathode contact hole may be formed by removing at least a portion of each of the pixel defining film PDL and the inorganic layer IOL. For example, referring to FIG. 8, the first to third cathode contact holes CCNT1, CCNT2, and CCNT3 may be formed by removing at least a portion of each of the pixel defining film PDL and the inorganic layer IOL, respectively.

The separator SPT may be formed on the second contact metal CMT2. The separator SPT may be disposed between the second contact metal CMT2 and the remaining light emitting portion REL.

The second pixel electrode CE may be connected (for example, electrically connected) to the second contact metal CMT2. Referring to FIG. 8, the second pixel electrode CE may contact at least a portion of the upper surface of the second contact metal CMT2. Referring to FIG. 8, the second pixel electrode CE may contact at least a portion of the side surface of the second contact metal CMT2.

By using the second contact metal CMT2, the problem of disconnection of the second pixel electrode CE may be alleviated or eliminated.

The second contact metal CMT2 may be connected to the first contact metal CMT1 through a cathode contact hole (for example, the first to third cathode contact holes CCNT1 to CCNT3). As a result, the second contact metal CMT2 may perform the function of blocking noise. Accordingly, the problem of interference occurring between adjacent anode electrodes (for example, the problem of interference occurring due to parasitic capacitance between adjacent anode electrodes) may be alleviated or eliminated.

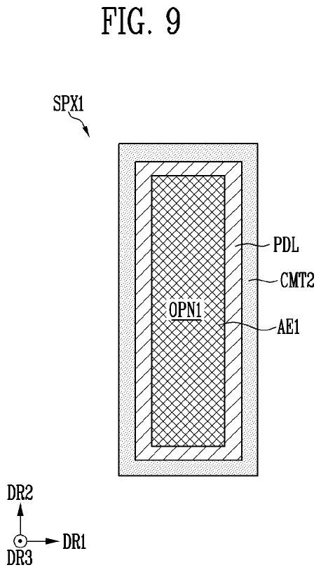

FIG. 9 illustrates a top view of the first sub-pixel SPX1 of FIG. 8 based on FIG. 2A.

Referring to FIG. 9, the first anode electrode AE1, the pixel defining film PDL, and the second contact metal CMT2 are mainly illustrated.

The pixel defining film PDL may be disposed surrounding the first anode electrode AE1.

The second contact metal CMT2 may be disposed while surrounding the first anode electrode AE1. Referring to FIG. 9, an embodiment in which the second contact metal CMT2 is disposed while completely surrounding the first anode electrode AE1 is shown. However, the embodiments of the present disclosure are not limited thereto. In some embodiments, at least a portion of the second contact metal CMT2 may be open around the first anode electrode AE1.

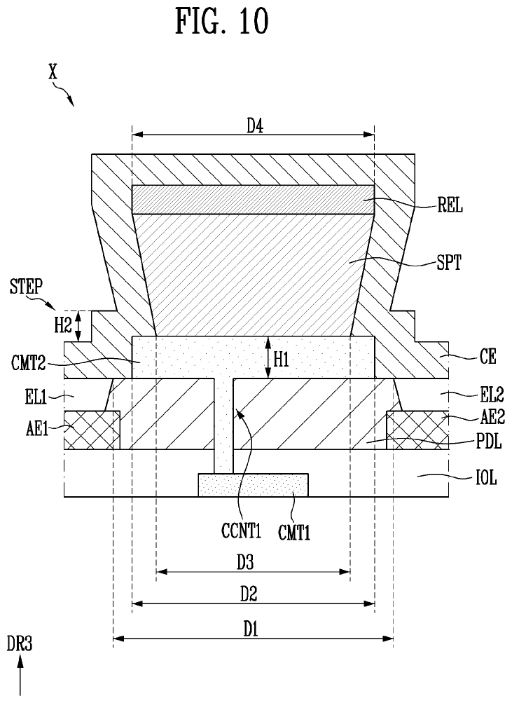

FIG. 10 illustrates an enlarged view of area “X” of FIG. 8.

In area “X”, the first contact metal CMT1, the inorganic layer IOL, the first and second anode electrodes AE1 and AE2, the pixel defining film PDL, the second contact metal CMT2, the separator SPT, the first and the second light emitting portions EL1 and EL2, and the second pixel electrode CE are mainly shown.

The first contact metal CMT1, the inorganic layer IOL, the first and second anode electrodes AE1 and AE2, the pixel defining film PDL, the second contact metal CMT2, the separators SPT, the first and second light emitting portions EL1 and EL2, and the second pixel electrode CE may be sequentially stacked.

An upper width (for example, a width in the first direction DR1) of the pixel defining film PDL may be a first distance D1. A width (for example, a width in the first direction DR1) of the second contact metal CMT2 may be a second distance D2. A lower width (for example, a width in the first direction DR1) of the separator SPT may be a third distance D3. An upper width (for example, a width in the first direction DR1) of the separator SPT may be a fourth distance D4.

The second distance D2 may be equal to or smaller than the first distance D1. The second contact metal CMT2 may be formed on an upper surface of the pixel defining film PDL.

The third distance D3 may be equal to or smaller than the second distance D2. The second pixel electrode CE may contact the upper surface or side surface of the second contact metal CMT2.

The fourth distance D4 may be larger than the third distance D3. The first light emitting portion EL1 and the second light emitting portion EL2 may be separated by the separator SPT of an inverted tapered shape.

A thickness (for example, a thickness in the third direction DR3) of the second contact metal CMT2 may be a first size H1. The second pixel electrode CE may have a step STEP as it contacts the second contact metal CMT2. Referring to FIG. 10, the second pixel electrode CE may have the step STEP formed as it contacts the upper and side surfaces of the second contact metal CMT2. A size of the step STEP may be a second size H2. The second size H2 may be the same as or similar to the first size H1. A lower end of the step STEP may be disposed on the same plane as the upper surface of the second contact metal CMT2.

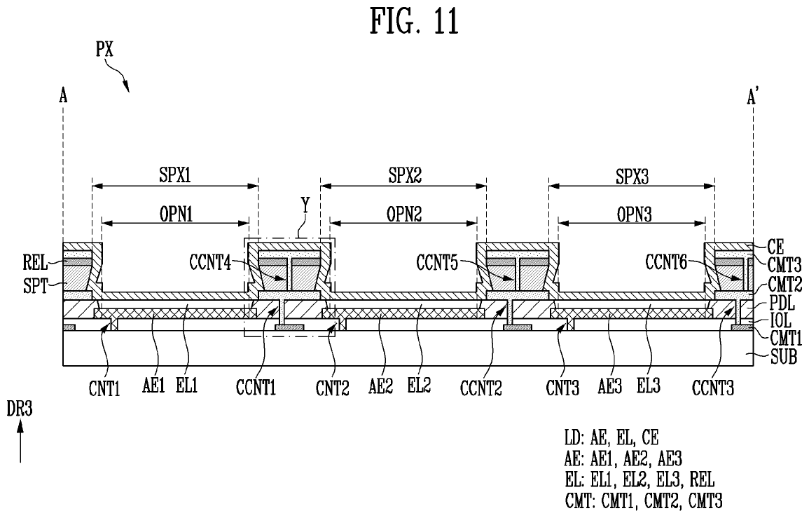

FIG. 11 illustrates a cross-sectional view taken along line A-A′ of the pixel of FIG. 2A to FIG. 2C according to another embodiment.

Referring to FIG. 11, the pixel PX may include a substrate SUB, a first contact metal CMT1, an inorganic layer IOL, a first pixel electrode AE, a pixel defining film PDL, a second contact metal CMT2, a separator SPT, an organic light emitting portion EL, a third contact metal CMT3, and a second pixel electrode CE.

The first contact metal CMT1, the inorganic layer IOL, the first pixel electrode AE, the pixel defining film PDL, the second contact metal CMT2, the separator SPT, the organic light emitting portion EL, the third contact metal CMT3, and the second pixel electrode CE may be sequentially formed.

The third contact metal CMT3 may be formed on the remaining light emitting portion REL. The third contact metal CMT3 may be disposed between the remaining light emitting portion REL and the second pixel electrode CE. The third contact metal CMT3 may be disposed between the separator SPT and the second pixel electrode CE. The third contact metal CMT3 may be connected (for example, electrically connected) to the second contact metal CMT2. Referring to FIG. 11, the third contact metal CMT3 may be connected (for example, electrically connected) to the second contact metal CMT2 through fourth, fifth, and sixth cathode contact holes CCNT4, CCNT5, and CCNT6.

Referring to FIG. 11, an embodiment in which the third contact metal CMT3 is disposed above all the separators SPT is shown. However, the embodiments of the present disclosure are not limited thereto, and the second contact metal CMT2 may be disposed above at least a portion of the separator SPT, and the second contact metal CMT2 may not be disposed above the remaining portion of the separator SPT. For example, the third contact metal CMT3 may be disposed below the separator SPT disposed in the boundary area between the first sub-pixel SPX1 and the second sub-pixel SPX2, and the third contact metal CMT3 may not be disposed below the separator SPT disposed in the boundary area between the second sub-pixel SPX2 and the third sub-pixel SPX3. For example, the third contact metal CMT3 may not be disposed below the separator SPT disposed in the boundary area between the first sub-pixel SPX1 and the second sub-pixel SPX2, and the third contact metal CMT3 may be disposed below the separator SPT disposed in the boundary area between the second sub-pixel SPX2 and the third sub-pixel SPX3.

The cathode contact hole may be formed by removing at least a portion of each of the remaining light emitting portion REL and the separator SPT. For example, referring to FIG. 11, the fourth to sixth cathode contact holes CCNT4, CCNT5, and CCNT6 may be respectively formed by removing at least a portion of each of the remaining light emitting portion REL and the separator SPT.

The second pixel electrode CE may be formed on the third contact metal CMT3. The second pixel electrode CE may be connected (for example, electrically connected) to the third contact metal CMT3. Referring to FIG. 11, the second pixel electrode CE may contact at least a portion of the upper surface of the third contact metal CMT3. Referring to FIG. 11, the second pixel electrode CE may contact at least a portion of the side surface of the third contact metal CMT3.

By using the third contact metal CMT3, the problem of disconnection of the second pixel electrode CE may be alleviated or eliminated.

The third contact metal CMT3 may be connected to the second contact metal CMT2 through a cathode contact hole (for example, the fourth to sixth cathode contact holes CCNT4 to CCNT6). As a result, the third contact metal CMT3 may perform the function of blocking noise. Accordingly, the problem of interference occurring between adjacent anode electrodes (for example, the problem of interference occurring due to parasitic capacitance between adjacent anode electrodes) may be alleviated or eliminated.

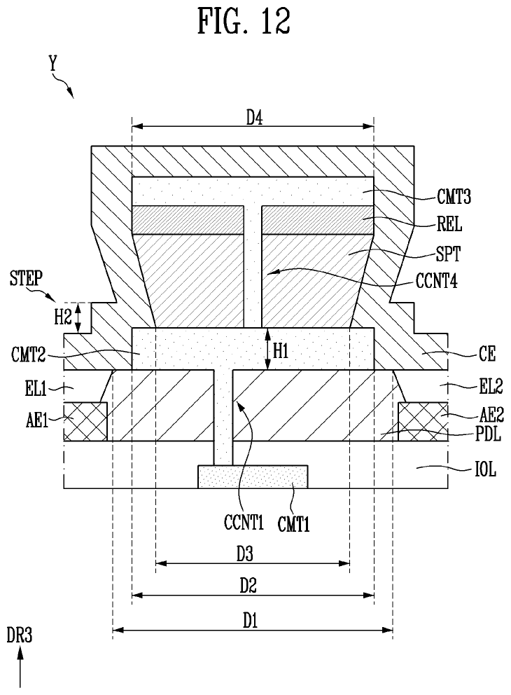

FIG. 12 illustrates an enlarged view of area “Y” of FIG. 11.

Compared with area “X” of FIG. 10, the third contact metal CMT3 may be further disposed on the remaining light emitting portion REL in area “Y”.

The third contact metal CMT3 may be connected (for example, electrically connected) to the second contact metal CMT2 through the fourth cathode contact hole CCNT4.

The width (for example, the width in the first direction DR1) of the third contact metal CMT3 may be the same (or substantially the same) as the width of the upper surface of the separator SPT. The width of the third contact metal CMT3 may be, for example, the fourth distance D4. The width of the third contact metal CMT3 may be the same (or substantially the same) as the width of the remaining light emitting portion REL.

According to the pixel, the manufacturing method thereof, and the display device including the same according to the embodiments of the present disclosure, it is possible to improve visibility.

According to the pixel, the manufacturing method thereof, and the display device including the same according to the embodiments of the present disclosure, it is possible to alleviate or eliminate interference caused by noise.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A pixel comprising:
a substrate;
a pixel circuit disposed on the substrate and including at least one transistor and at least one capacitor;
a first contact metal disposed on the substrate and to which a constant voltage is applied;
an inorganic layer covering the first contact metal;
a first pixel electrode disposed on the inorganic layer and electrically connected to the pixel circuit;
a pixel defining film disposed on the first pixel electrode;
a second contact metal disposed on the pixel defining film and electrically connected to the first contact metal;
a separator disposed on the second contact metal;
an organic light emitting portion disposed on the first pixel electrode; and
a second pixel electrode disposed on the organic light emitting portion and connected to the second contact metal.

2. The pixel of claim 1, wherein
the constant voltage is a low potential voltage.

3. The pixel of claim 1, wherein
the separator has a reverse tapered shape.

4. The pixel of claim 1, wherein
the second contact metal is connected to the first contact metal through a cathode contact hole formed by removing at least a portion of the pixel defining film and at least a portion of the inorganic layer.

5. The pixel of claim 1, wherein
a plurality of sub-pixels are disposed on the substrate, and each of the plurality of sub-pixels includes the pixel circuit;
the first pixel electrode includes:
a first anode electrode of a first sub-pixel among the plurality of sub-pixels;
a second anode electrode of a second sub-pixel among the plurality of sub-pixels; and
a third anode electrode of a third sub-pixel among the plurality of sub-pixels, and
the pixel defining film is disposed in a boundary area between the first anode electrode and the second anode electrode and a boundary area between the second anode electrode and the third anode electrode.

6. The pixel of claim 5, wherein
the first contact metal and the second contact metal are disposed in the boundary area between the first anode electrode and the second anode electrode, and the boundary area between the second anode electrode and the third anode electrode.

7. The pixel of claim 5, wherein
the first contact metal and the second contact metal are disposed in the boundary area between the first anode electrode and the second anode electrode, and are not disposed in the boundary area between the second anode electrode and the third anode electrode.

8. The pixel of claim 5, wherein
the second contact metal completely surrounds the first anode electrode.

9. The pixel of claim 5, wherein
the second contact metal surrounds the first anode electrode, and at least a portion of the second contact metal is open around the first anode electrode.

10. The pixel of claim 1, wherein
a width of an upper surface of the pixel defining film is a first distance, a width of the second contact metal is a second distance, and the second distance is less than or equal to the first distance.

11. The pixel of claim 1, wherein
a width of the second contact metal is a second distance, a width of a lower surface of the separator is a third distance less than or equal to the second distance, and a width of an upper surface of the separator is greater than or equal to the third distance.

12. The pixel of claim 1, wherein
the second pixel electrode has a step of a size corresponding to a thickness of the second contact metal.

13. The pixel of claim 12, wherein
a lower end of the step is disposed on the same plane as an upper surface of the second contact metal.

14. The pixel of claim 1, further comprising
a third contact metal disposed on the separator and connected to the second contact metal and the second pixel electrode.

15. The pixel of claim 14, wherein
the third contact metal is connected to the second contact metal through a cathode contact hole formed by removing at least a portion of the separator.

16. A method of manufacturing a pixel, comprising:
forming a first contact metal on a backplane substrate;
forming an inorganic layer on the first contact metal;
forming a first pixel electrode on the inorganic layer and electrically connecting the first pixel electrode and the backplane substrate;
forming a pixel defining film on the first pixel electrode;
forming a second contact metal on the pixel defining film, and electrically connecting the second contact metal and the first contact metal in an area in which at least a portion of the pixel defining film is removed;
forming a separator on the second contact metal;
forming an organic light emitting portion on the first pixel electrode and the separator; and
forming a second pixel electrode on the organic light emitting portion and electrically connecting the second pixel electrode and the second contact metal.

17. The method of claim 16, wherein
the separator is formed to have a reverse tapered shape.

18. The method of claim 16, further comprising
removing at least a portion of each of the separator and the organic light emitting portion to form a third contact metal connected to the second contact metal, and
wherein the second pixel electrode is further connected to the third contact metal.

19. A display device comprising:
a plurality of pixels disposed on a substrate, each of which includes a pixel circuit;
a plurality of scan lines disposed on the substrate and connected to the pixel circuits of the plurality of pixels; and
a plurality of data lines disposed on the substrate and connected to the pixel circuits of the plurality of pixels,
wherein at least one of the plurality of pixels includes:
a first contact metal disposed on the substrate and to which a constant voltage is applied;
an inorganic layer at least partially covering the first contact metal;
a first pixel electrode disposed on the inorganic layer and electrically connected to the pixel circuit;
a pixel defining film disposed on the first pixel electrode;
a second contact metal disposed on the pixel defining film and electrically connected to the first contact metal;
a separator disposed on the second contact metal;
an organic light emitting portion disposed on the first pixel electrode; and
a second pixel electrode disposed on the organic light emitting portion and connected to the second contact metal.

20. The display device of claim 19, wherein
the substrate is a silicon substrate.
